(19) United States
(12) Patent Application Publication
(10) Pub. No.: US 2026/0060121 A1
(43) Pub. Date: Feb. 26, 2026

(54) ELECTRONIC DEVICE HAVING SUBSTRATE CAVITIES FOR POSITIONING ELECTRONIC UNITS AND MANUFACTURING METHOD THEREOF

(71) Applicant: InnoLux Corporation, Miao-Li County (TW)

(72) Inventors: Kuang-Ming FAN, Miao-Li County (TW); Ju-Li WANG, Miao-Li County (TW)

(73) Assignee: InnoLux Corporation, Miao-Li County (TW)

(21) Appl. No.: 19/278,841

(22) Filed: Jul. 24, 2025

Related U.S. Application Data
(60) Provisional application No. 63/685,265, filed on Aug. 21, 2024.

(30) Foreign Application Priority Data
Mar. 27, 2025 (CN) 202510370731.3

(51) Int. Cl. H01L 23/13; H01L 21/48; H01L 21/56; H01L 23/00; H01L 23/31; H01L 23/544; H01L 25/065

(52) U.S. Cl. CPC H01L 23/13; H01L 21/481; H01L 21/486; H01L 21/561; H01L 23/3107; H01L 24/24; H01L 24/29; H01L 24/32; H01L 24/73; H01L 24/82; H01L 24/83; H01L 24/92; H01L 24/97; H01L 25/0655; H01L 23/544; H01L 2224/24137; H01L 2224/29011; H01L 2224/29082; H01L 2224/32225; H01L 2224/73267; H01L 2224/82986; H01L 2224/83191; H01L 2224/83986; H01L 2224/92244; H01L 2224/97

(57) ABSTRACT

An electronic device includes a substrate, a through hole, a first electronic unit, a second electronic unit, a circuit structure, and a third electronic unit. The substrate has a first surface, a second surface opposite the first surface, a first cavity, and a second cavity. A sidewall of the first cavity is connected to the first surface, and a sidewall of the second cavity is connected to the first surface. The through hole extends through the substrate, and a sidewall of the through hole is connected to the first surface and the second surface. The first electronic unit is disposed in the first cavity. The second electronic unit is disposed in the second cavity. The circuit structure is disposed on the first electronic unit and the second electronic unit. The bottom surfaces of the first and second cavities have a roughness ranging from 0 to 2 micrometers.

### CROSS REFERENCE TO RELATED APPLICATION

This application claims the benefit of U.S. Provisional Application No. 63/685,265, filed on August 21, 2024. The content of the application is incorporated herein by reference.

### BACKGROUND OF THE DISCLOSURE

### 1. Field of the Disclosure

The disclosure relates to an electronic device and a manufacturing method thereof, and more particularly, to an electronic device and a manufacturing method thereof that utilize cavities and/or through holes (through vias) to suppress the shift of electronic units.

### 2. Description of the Prior Art

In current Panel Level Packaging (PLP) processes, when attaching and encapsulating dies, the total die shift may reach as high as 25 to 50 micrometers, with the encapsulation process having a particularly significant impact. This is due to non-uniform flow of the encapsulation material during mold filling, causing die shift. Such non-uniform flow results in variations in die shift amounts at different locations, and may even exhibit a trend of increasing shift from the center outwards. Although the compensation may be applied for a single die by using Die Level Compensation (DLC), for a multi-chip package, die shift makes alignment of inter-chip traces difficult, severely impacting the yield rate. Furthermore, die shift significantly increases the design complexity of probe cards for subsequent panel testing stages, reducing production efficiency. Therefore, effectively controlling die shift range has become the key to improving PLP process yield rates.

### SUMMARY OF THE DISCLOSURE

According to an embodiment of the disclosure, an electronic device is provided, which comprises a substrate, a through hole, a first electronic unit, a second electronic unit, a circuit structure, and a third electronic unit. The substrate has a first surface, a second surface opposite the first surface, a first cavity, and a second cavity. A sidewall of the first cavity is connected to the first surface, and a sidewall of the second cavity is connected to the first surface. The through hole extends through the substrate, and a sidewall of the through hole is connected to the first surface and the second surface. The first electronic unit is disposed in the first cavity. The second electronic unit is disposed in the second cavity. The circuit structure is disposed on the first electronic unit and the second electronic unit. The third electronic unit is disposed on the circuit structure. The roughness of the bottom surface of the first cavity and the roughness of the bottom surface of the second cavity range from 0 to 2 micrometers.

According to an embodiment of the disclosure, a manufacturing method for an electronic device is provided, which comprises: providing a substrate having a first surface and a second surface opposite the first surface; forming a through hole in the substrate, wherein a sidewall of the through hole is connected to the first surface and the second surface of the substrate; forming a first cavity and a second cavity in the substrate, wherein a sidewall of the first cavity is connected to the first surface, a sidewall of the second cavity is connected to the first surface, and the roughness of the bottom surface of the first cavity and the roughness of the bottom surface of the second cavity range from 0 to 2 micrometers; disposing a first electronic unit in the first cavity; disposing a second electronic unit in the second cavity; forming a protection layer on the substrate, covering the first electronic unit and the second electronic unit and filling the first cavity and the second cavity; forming a circuit structure on the first electronic unit and the second electronic unit; and disposing a third electronic unit on the circuit structure.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a top view of a package structure according to an embodiment of the present disclosure.

FIG. 2 is a schematic structural diagram corresponding to two cavities and a through hole of the package structure shown in FIG. 1.

FIG. 3 to FIG. 5 are schematic structural diagrams illustrating a manufacturing method of the package structure at different steps according to an embodiment of the present disclosure.

FIG. 6 to FIG. 8 are schematic structural diagrams illustrating a manufacturing method of the package structure at different steps according to another embodiment of the present disclosure.

FIG. 9 illustrates several ways of disposing the electronic unit of the package structure shown in FIG. 1 into the cavity.

FIG. 10 is a top view of a package structure according to another embodiment of the present disclosure.

FIG. 11 is a cross-sectional view of the package structure shown in FIG. 10 along the dashed line 11-11′.

FIG. 12 to FIG. 15 are schematic cross-sectional views of electronic devices according to different embodiments of the present disclosure, respectively.

### DETAILED DESCRIPTION

The content of the present disclosure will be described in detail below in conjunction with specific embodiments and drawings. To make the content of the present disclosure clearer and easier to understand, the following drawings may be simplified schematic diagrams, and the components therein may not be drawn to scale. Furthermore, the number and size of each component in the drawings are only for illustration and are not intended to limit the scope of the present disclosure.

Throughout the specification and the appended claims of the present disclosure, certain terms are used to refer to specific components. Those skilled in the art should understand that electronic device manufacturers may refer to the same component by different names, and this document does not intend to distinguish between components that have the same function but different names. In the following description and claims, terms such as “comprising” and “including” are open-ended terms and should therefore be interpreted as “including but not limited to . . . ”.

Ordinal numbers such as “first,” “second,” etc., used in the specification and claims to modify claim elements do not in themselves imply or represent any prior ordinal precedence, nor do they represent the order of one claim element relative to another, or the order in manufacturing methods. The use of such ordinal numbers is solely to enable a claim element having a certain name to be clearly distinguished from another claim element having the same name.

Furthermore, when an element or layer is referred to as being connected to another element or layer, it should be understood that the element or layer is directly physically or electrically connected to the other element or layer, or that the two may be indirectly physically or electrically connected through other elements or layers. Conversely, when an element or layer is referred to as being “directly connected to” another element or layer, it should be understood that there are no other elements or layers physically or electrically connecting the two. The term “connected” may include means of “direct contact” or “indirect contact.” Additionally, the terms “electrically connected” or “coupled” include any means of direct and indirect electrical connection.

Herein, when an element is referred to as being “disposed on” another element, it does not limit the process steps or sequence of forming said element and said other element. Herein, when an element is referred to as being “disposed on” another element, it may include an element disposed on a sidewall of the other element.

In the text, terms like “about,” “substantially,” or “approximately” generally indicate a range within 20%, 10%, 5%, 3%, 2%, 1%, or 0.5% of a given value. The quantity given here is an approximate quantity, meaning that even without specific reference to “about,” “substantially,” or “approximately,” the meaning of “about,” “substantially,” or “approximately” may still be implied.

The term “between value A and value B” is interpreted to include value A and value B, or conditions including at least one of value A and value B, as well as other values between value A and value B.

In the disclosure, measurement methods for depth, thickness, length, width, and aperture can be obtained using an optical microscope (OM), electron microscope (e.g., Scanning Electron Microscope, SEM), or other methods, but are not limited thereto.

In the disclosure, the definition for determining roughness can be observed by SEM. On the uneven surface of the object under test, the high-low distance difference between the peaks and valleys of the surface undulations can be seen, which is defined as roughness. For example, if the peaks and valleys of the surface undulations have a distance difference of 0.15 micrometers (μm) to 1 μm, its roughness is defined as 0.15 micrometers to 1 micrometer, and so forth. The measurement for determining roughness can include using SEM, Transmission Electron Microscope (TEM), etc., to observe the condition of surface undulations under an appropriate identical magnification, and comparing the undulation condition of a sample of unit length (e.g., 10 μm) provides its roughness range. Here, “appropriate magnification” means that at least one surface can show at least 10 undulating peaks of roughness (Rz) or average roughness (Ra) within the field of view at this magnification.

It should be understood that the following embodiments can be implemented by replacing, reorganizing, or mixing features from multiple different embodiments without departing from the spirit of the present disclosure to complete other embodiments. Features among various embodiments can be arbitrarily mixed and matched as long as they do not violate the spirit of the disclosure or conflict with each other.

Unless otherwise defined, all terms (including technical and scientific terms) used herein have the same meaning as commonly understood by one of ordinary skill in the art to which the disclosure belongs. It is understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The package structure of the present disclosure can be applied to any type of electronic device. The electronic device may include, for example, a power module, a semiconductor package device, a display device, a light-emitting device, a sensing device, an antenna device, a touch device, a splicing device, a package structure, or other suitable electronic devices, but is not limited thereto. The electronic device may be, for example, a bendable, stretchable, foldable, rollable, and/or flexible electronic device, but is not limited thereto. The display device may be applied, for example, to notebook computers, public displays, splicing displays, automotive displays, touch displays, televisions, monitors, smartphones, tablet computers, light source modules, lighting equipment, military equipment, or electronic devices applied to the aforementioned products, but is not limited thereto. The sensing device may be, for example, a sensing device used to detect changes in capacitance, light, thermal energy, or ultrasound, but is not limited thereto. The sensing device may include, for example, biosensors, touch sensors, fingerprint sensors, other suitable sensors, or combinations of the aforementioned types of sensors. The display device may include, for example, liquid crystal molecules, light-emitting diodes, fluorescent material, phosphor material, other suitable display media, or combinations of the foregoing, but is not limited thereto. The light-emitting diode may include, for example, organic light-emitting diodes (OLED), mini LEDs, micro LEDs, or quantum dot light-emitting diodes (QD, e.g., QLED, QDLED), or other suitable materials, or any arrangement combination of the aforementioned materials, but is not limited thereto. The antenna device may be, for example, a liquid crystal antenna, a varactor diode antenna, or other types of antenna types, but is not limited thereto. The splicing device may include, for example, a splicing display device or a splicing antenna device, but is not limited thereto. Furthermore, the external shape of the electronic device may be, for example, rectangular, circular, polygonal, a shape with curved edges, curved, or other suitable shapes. The electronic device may have peripheral systems such as a driving system, a control system, a light source system, a shelf system, etc. The electronic device may include electronic units, wherein the electronic units may include passive components and active components, such as capacitors, resistors, inductors, diodes, transistors, sensors, silicon photonics, etc. It should be noted that the electronic device of the present disclosure may be various combinations of the aforementioned devices, but is not limited thereto. The manufacturing method of the package structure in the present disclosure can be applied, for example, in wafer-level package (WLP) processes or panel-level package (PLP) processes, wherein the WLP or PLP processes may include chip-first processes or chip-last processes, but is not limited thereto. The package structure of the present disclosure can be applied, for example, to power modules, display devices, light-emitting devices, backlight devices, antenna devices, sensing devices, or splicing devices, but is not limited thereto. The package structure may include High Bandwidth Memory (HBM) packages, System on a Chip (SoC), System in a Package (SiP), antenna in package (AiP), Co-packaged Optics (CPO), or various combinations of the aforementioned devices, but is not limited thereto.

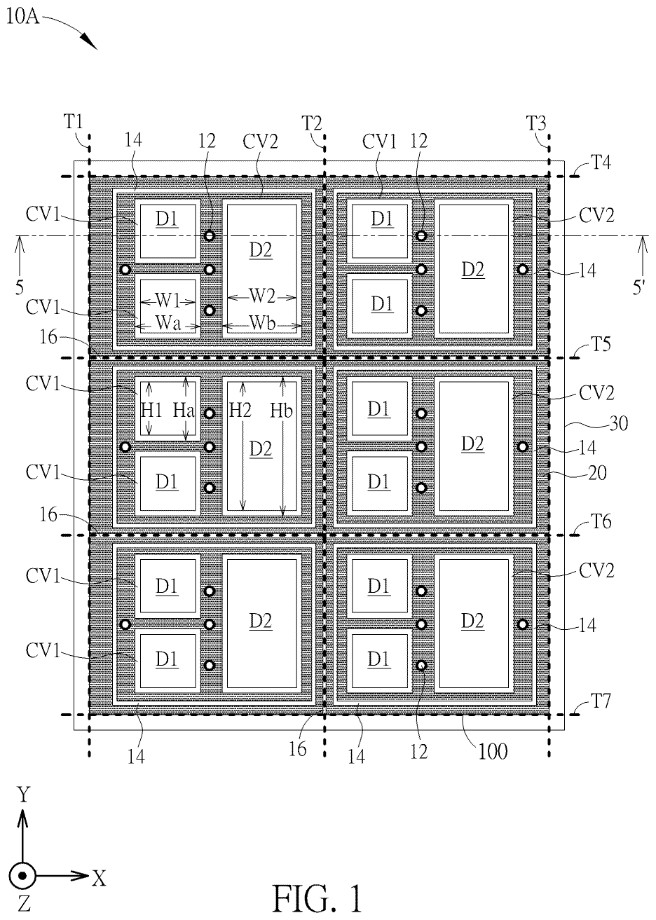

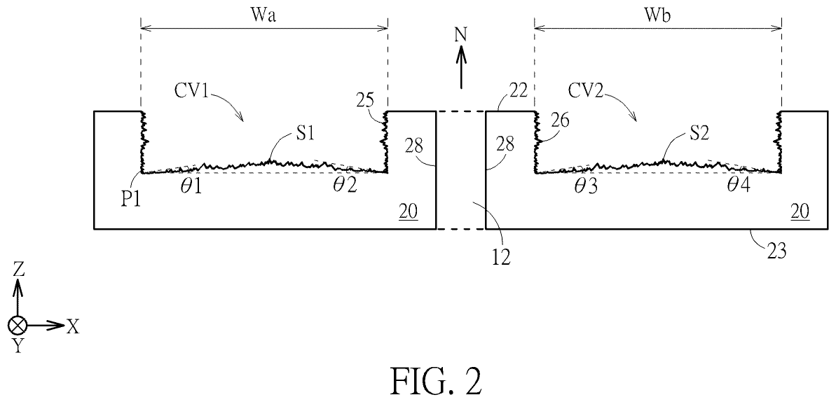

At least one component of the electronic device of the present disclosure can be fabricated first through WLP processes or PLP processes. Please refer to FIG. 1 and FIG. 2. FIG. 1 is a top view of a package structure 10A according to an embodiment of the present disclosure, and FIG. 2 is a schematic structural diagram corresponding to the cavity CV1, the cavity CV2, and the through hole 12 of the package structure 10A shown in FIG. 1. FIG. 1 and FIG. 2 use three axes X, Y, and Z to represent directionality, and the directions of the three axes X, Y, and Z are different from each other. In one embodiment, the three axes X, Y, and Z may be mutually perpendicular. The package structure 10A may be an intermediate product for manufacturing the electronic device of the present disclosure, which can be manufactured through WLP processes or PLP processes. After the manufacturing of the package structure 10A is completed, the package structure 10A may be cut along the cutting lines T1 to T7 to produce six identical components 100. It is worth noting that the number of the components 100 obtained after cutting can be adjusted according to the design. Through WLP or PLP processes, combined with flexible cutting methods, the present disclosure can effectively meet the diversified production needs of different electronic products and achieve high customization. Furthermore, such a process not only simplifies subsequent assembly steps but also more effectively reduces production costs, achieves product miniaturization, lightweighting, and high integration, meeting the increasingly demanding requirements of the electronic product market. Additionally, the aforementioned process of cutting the package structure 10A may include, for example, laser cutting, blade dicing, other suitable processes, or any combination thereof. It should be noted that the component 100 itself can be regarded as an electronic device, or it can be applied to any suitable electronic device.

The package structure 10A comprises a substrate 20. The substrate 20 may include a wafer, glass, polymer glass, silicon-containing transparent material, optical layer, acrylic sheet, or the above combinations or other transparent materials, and has certain stiffness and insulation properties. The substrate 20 has a first surface 22, a second surface 23, a plurality of cavities CV1, and a plurality of cavities CV2. The second surface 23 is opposite the first surface 22. A sidewall 25 of each cavity CV1 is connected to the first surface 22, and a sidewall 26 of each cavity CV2 is connected to the first surface 22. Additionally, there are a plurality of through holes 12 extending through the substrate 20, and a sidewall 28 of each through hole 12 is connected to the first surface 22 and the second surface 23. The through holes 12, cavities CV1, and cavities CV2 may be formed in the substrate 20 by means of mechanical processing, laser processing, chemical etching, or composite processing. For example, a laser modification process may be first performed on the substrate 20, so that the laser beam changes the material bonding of the substrate 20 at predetermined locations for forming the through holes 12, cavities CV1, and cavities CV2. Depending on the material of the substrate 20, the wavelength of the laser used in the laser irradiation process may differ, and the absorption rate of the substrate 20 for the laser wavelength may be greater than or equal to 70%. Then, an etching process (such as, but not limited to, a wet etching process) is performed to remove the material of the modified portion of the substrate 20, thereby forming the through holes 12, cavities CV1, and cavities CV2. The etching process may include, for example, wet etching processes using an etchant or other suitable processes. According to some embodiments, the etchant may include acidic or alkaline liquids. For example, the acidic etchant comprises hydrofluoric acid, and the alkaline etchant comprises sodium hydroxide, but not limited thereto. The etching process referred to in the present disclosure can be performed, for example, from the first surface 22 or the second surface 23 of the substrate 20 to form the through holes 12, or simultaneously from the first surface 22 and the second surface 23 of the substrate 20, but is not limited thereto. In some embodiments, in a cross-sectional view, the profile of the through hole 12 may be rectangular, trapezoidal, inversely trapezoidal, dumbbell-shaped, hourglass-shaped, or other suitable shapes, but the present disclosure is not limited to the above. The through holes 12 extend through the substrate 20 along the Z-axis direction. When the substrate 20 is a glass substrate, the through holes 12 are through glass vias (TGVs). The cavities CV1 and the cavities CV2 may not extend through the substrate 20, for example, being referred to as blind holes. In variant embodiments, the cavities CV1 and the cavities CV2 may extend through the substrate 20. In the X-axis direction or any planar direction, the width of the cavities CV1 and the cavities CV2 are respectively greater than the width of the through holes 12. In some embodiments, each cavity CV2 may be adjacent to at least one cavity CV1. One electronic unit D1 is disposed in each cavity CV1, and one electronic unit D2 is disposed in each cavity CV2. In some embodiments of the present disclosure, a plurality of electronic units D1 may be disposed in one cavity CV1. In some embodiments of the present disclosure, a plurality of electronic units D2 may be disposed in one cavity CV2. The electronic unit D1 and the electronic unit D2 may comprise, for example, integrated circuit chips, redistribution layer (RDL) units, display units, light-emitting units, sensing units, antenna units, touch units, package units, or other suitable electronic units, but are not limited thereto. Furthermore, in the direction parallel to the X-axis, the width Wa of the cavity CV1 is greater than the width W1 of the electronic unit D1, and the width Wb of the cavity CV2 is greater than the width W2 of the electronic unit D2. Additionally, in the direction parallel to the Y-axis, the length Ha of the cavity CV1 is greater than the length H1 of the electronic unit D1, and the length Hb of the cavity CV2 is greater than the length H2 of the electronic unit D2. The length Hb of the cavity CV2 may be greater than the length Ha of the cavity CV1. For example, the length Hb may be approximately greater than or equal to twice the length Ha, but this is not limited to that. In the top view of the package structure 10A, an interval of 5 to 10 micrometers is left between each side of the electronic unit D1 and the edge of the cavity CV1, and an interval of 5 to 10 micrometers is left between each side of the electronic unit D2 and the edge of the cavity CV2.

Additionally, when the substrate 20 comprises transparent material, the transmittance of the substrate 20 to white light may be, for example, greater than 80%. And the substrate 20 has certain stiffness and insulation properties. That is, the stiffness of the substrate 20 may be greater than the stiffness of the subsequently formed circuit structure. For example, the stiffness of the substrate 20 is greater than the stiffness of the insulating layer of the circuit structure, so that the substrate 20 can mitigate warpage when used to carry the circuit structure, but the present disclosure is not limited thereto. Alternatively, the dielectric loss of the substrate 20 is smaller than the dielectric loss of the insulating layer of the circuit structure, so that when the substrate 20 is used to carry the circuit structure, it can enhance the electrical characteristics of the electronic device (such as the electronic devices 1200, 1300, 1400, and 1500 mentioned in the description below), but the present disclosure is not limited thereto.

In the package structure 10A shown in FIG. 1, although one through hole 12 is located between one adjacent cavity CV1 and one adjacent cavity CV2, the position and number of the through holes 12 are not limited to what is shown in FIG. 1. For example, in some embodiments, along the X-axis direction, at least one through hole 12 may be disposed on both sides of the cavity CV1, and at least one through hole 12 may also be disposed on the side of the cavity CV2 opposite to the cavity CV1. Furthermore, in some embodiments, on one side of the sidewall of the cavity CV2 adjacent to the cavity CV1 and parallel to the Y-axis direction, a plurality of through holes 12 may be disposed, arranged sequentially along the Y-axis and between the cavity CV2 and the cavity CV1. In other words, one or more through holes 12 may be respectively disposed between the adjacent cavity CV1 and cavity CV2, on the side of the cavity CV1 opposite to the cavity CV2, and on the side of the cavity CV2 opposite to the cavity CV1, and their number is not limited to that shown in FIG. 1.

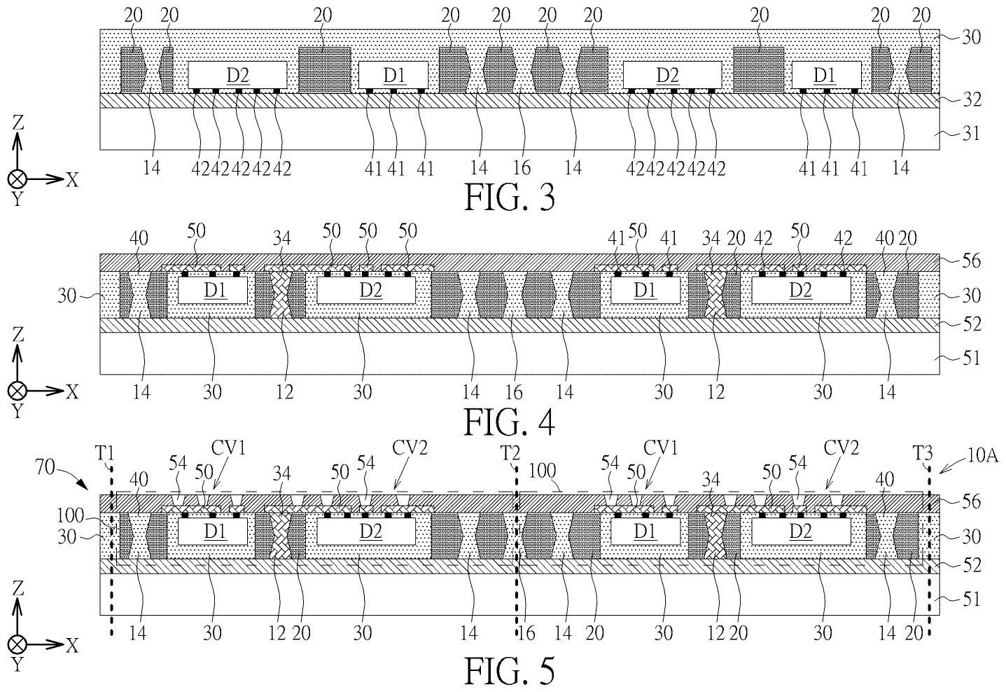

During the packaging process of the package structure 10A, a protection layer 30 may be formed on the electronic unit D1, the electronic unit D2, and the substrate 20 to fully cover the substrate 20 and the components disposed thereon. The packaging process may include, for example, a molding process or other suitable processes. In some embodiments, the packaging process may include, for example, a thermal process. In some embodiments of the present disclosure, annular grooves 14 and linear grooves 16 may be formed in the substrate 20. During the packaging process of the package structure 10A, the protection layer 30 can fill the grooves 14 and the grooves 16. Among them, the protection layer 30 filled in the grooves 14 can serve as a crack stopper, and the protection layer 30 filled in the grooves 16 can eventually form the sidewall of the substrate 20 after the package structure 10A is cut. It should be noted that since both the grooves 14 and the grooves 16 may extend through the substrate 20, the grooves 14 and the grooves 16 can also be regarded as the aforementioned through holes 12, as shown in the cross-sectional views (e.g., FIG. 3 to FIG. 8), but the present disclosure is not limited thereto.

According to the present disclosure, the roughness of the bottom surface S1 of the cavity CV1 and the roughness of the bottom surface S2 of the cavity CV2 are both range from 0 to 2 micrometers, so as to ensure that the electronic unit D1 and the electronic unit D2 can be closely bonded with the cavity CV1 and the cavity CV2 respectively, enhancing the reliability of electrical connection. The method for determining roughness can involve observing the surfaces of cavity CV1 and cavity CV2 by using Scanning Electron Microscopy (SEM), Transmission Electron Microscopy (TEM), etc. High-resolution images from SEM allow for clear observation of the details of surface undulations and measurement of the distance between adjacent peaks and valleys. Generally, this distance falls between 0.15 and 1 micrometer. By selecting an appropriate magnification, ensuring that a sufficient number of surface undulations can be observed within the field of view, quantitative analysis can be performed. Here, “appropriate magnification” means that at least 10 undulating peaks can be seen within the field of view of at least one surface at this magnification.

Furthermore, in other embodiments of the present disclosure, to further optimize the bonding effect, the difference between the roughness of the bottom surface S1 of the cavities CV1 and the roughness of the bottom surface S2 of the cavities CV2 can be controlled to be less than 1.2 micrometers. Such fine surface treatment helps reduce contact resistance, improve signal transmission efficiency, and enhance the overall performance of the product. In one embodiment of the present disclosure, the cavity CV1 has a bottom corner θ1 and a bottom corner θ2, and the cavity CV2 has a bottom corner θ3 and a bottom corner θ4, where the difference between bottom corner θ1 and bottom corner θ2, and the difference between bottom corner θ3 and bottom corner θ4 are both greater than or equal to 0 degrees and less than or equal to 10 degrees, to further ensure that electronic unit D1 and electronic unit D2 can be closely bonded with cavity CV1 and cavity CV2, respectively. The bottom corner described in the disclosure refers to the included angle between the extension direction of the bottom edge of the cavity and the X-axis direction, at the junction P1 of the cavity sidewall and the bottom edge of the cavity, and so forth. According to the present disclosure, since the manufacturing method of cavity CV1 and cavity CV2 can include (but is not limited to) first modifying the substrate 20 via a laser modification process and then removing the modified portion of the substrate 20 via a wet etching process, both the bottom surface S1 of cavity CV1 and the bottom surface S2 of cavity CV2 have smaller roughness, and/or the difference between the bottom surface S2 and the bottom surface S1 can be made smaller.

Please refer to FIG. 3 to FIG. 5. FIG. 3 to FIG. 5 are schematic structural diagrams illustrating the manufacturing method of the package structure 10A according to an embodiment of the present disclosure at different steps. Among them, FIG. 5 can be a schematic cross-sectional view of the package structure 10A corresponding to FIG. 1 along the dashed line 5-5′. In this embodiment, the electronic unit D1 comprises a plurality of contact pads 41, and the electronic unit D2 comprises a plurality of contact pads 42. The surface of the electronic unit D1 and the electronic unit D2 having the contact pads 41 or 42 is the active surface, and the other surface is the back surface. The substrate 20 can be fixed onto the carrier board 31 by an adhesive layer 32. After the substrate 20 is fixed on the carrier board 31, the through hole 12, cavity CV1, cavity CV2, groove 14, and groove 16 of the substrate 20 can be formed by means of mechanical processing, laser processing, chemical etching, or composite processing. In another embodiment of the present disclosure, the through hole 12, cavity CV1, cavity CV2, groove 14, and groove 16 of the substrate 20 can be formed first, and then the substrate 20 is fixed onto the carrier board 31. After the cavity CV1 and cavity CV2 of the substrate 20 are formed, as shown in FIG. 3, the electronic unit D1 and the electronic unit D2 are respectively disposed in the cavity CV1 and the cavity CV2 with their contact pads 41 and 42 facing in the direction opposite to the Z-axis, and covered with a protection layer 30 over the electronic unit D1, electronic unit D2, and substrate 20, i.e., disposed in a face-down manner facing the carrier board 31. In the embodiment shown in FIG. 3, the cavity CV1 and the cavity CV2 can be through holes extending through the substrate 20, and the electronic unit D1 and the electronic unit D2 can be fixed onto the surface of the carrier board 31 by the adhesive layer 32 or other adhesive layer material, but is not limited thereto. Next, a portion of the protection layer 30 disposed on the substrate 20 can be selectively removed, so that the surface of the protection layer 30 is flush with the surface of the substrate 20 (not shown). Then, as shown in FIG. 4, the structure in FIG. 3 can be flipped and fixed onto another carrier board 51 by an adhesive layer 52, and then the carrier board 31 and the adhesive layer 32 shown in FIG. 3 are removed, so that the active surfaces of the electronic unit D1 and the electronic unit D2 face the Z-axis direction. In other words, the substrate 20 is fixed onto the carrier board 51 by the adhesive layer 52 as shown in FIGS. 4 and 5. Subsequently, the through hole 12 is formed in the substrate 20, and conductive material is filled into the through hole 12 to form a conductive structure 34. The filled conductive material may include, but is not limited to, copper, aluminum, gold, silver. Next, a plurality of conductive structures 50 coupled to the contact pads 41 and 42 are formed, and an insulating layer 56 is formed on the conductive structure 50. The conductive structure 50 may comprise one or more conductive layers (represented by one conductive layer in FIG. 4), and the conductive material included therein may be the same as or different from the conductive material filled in the through hole 12. Finally, as shown in FIG. 5, a plurality of conductive structures 54 coupled to the conductive structure 50 are formed in the insulating layer 56, thus completing the fabrication of the package structure 10A. The conductive material included in the conductive structure 54 may be the same as or different from the conductive structure 50 and/or the conductive structure 34. Afterwards, as described above, the package structure 10A can be cut along cutting lines T1 to T7 to produce six identical components 100. Among them, the conductive structure 50, the conductive structure 54, and the insulating layer 56 can constitute the circuit structure 70 of the component 100, which can be regarded, for example, as a redistribution layer (RDL) structure disposed on the electronic unit D1 and the electronic unit D2. Furthermore, the protection layer 30 filled in the groove 14 can serve as a crack stopper 40, which surrounds the electronic unit D1, electronic unit D2, conductive structure 50, conductive structure 54, and conductive structure 34 to provide support and protection functions, as shown in FIG. 1. Additionally, the aforementioned adhesive layer 32 and adhesive layer 52 may include, for example, thermal release tape (HRT), light-to-heat-conversion (LTHC) release coating, underfill material, or other suitable materials. Furthermore, the carrier board 31 and the carrier board 51 may include, for example, steel plates, aluminum plates, ceramic plates, composite material plates, or other suitable materials. It should be noted that, according to the present disclosure, each component 100 itself can be regarded as an independent electronic device, or each component 100 can be applied to suitable electronic devices.

In the above embodiment, the adhesive layer 32 and the adhesive layer 52 are complete single layers. However, to further address the shift issue of electronic unit D1 and electronic unit D2, the present disclosure provides another innovative solution: partitioning the adhesive layer 32 and/or the adhesive layer 52 into a plurality of independent parts. During the process, the adhesive layer may generate an outward pulling force, while the protection layer 30 generates an inward shrinking force. The interaction of these two forces may cause dies (e.g., electronic units D1 and D2) at different positions to experience varying degrees of shift. Therefore, by partitioning the adhesive layer, these stresses can be dispersed, mitigating the extent of die shift, especially for dies located at the edges or corners.

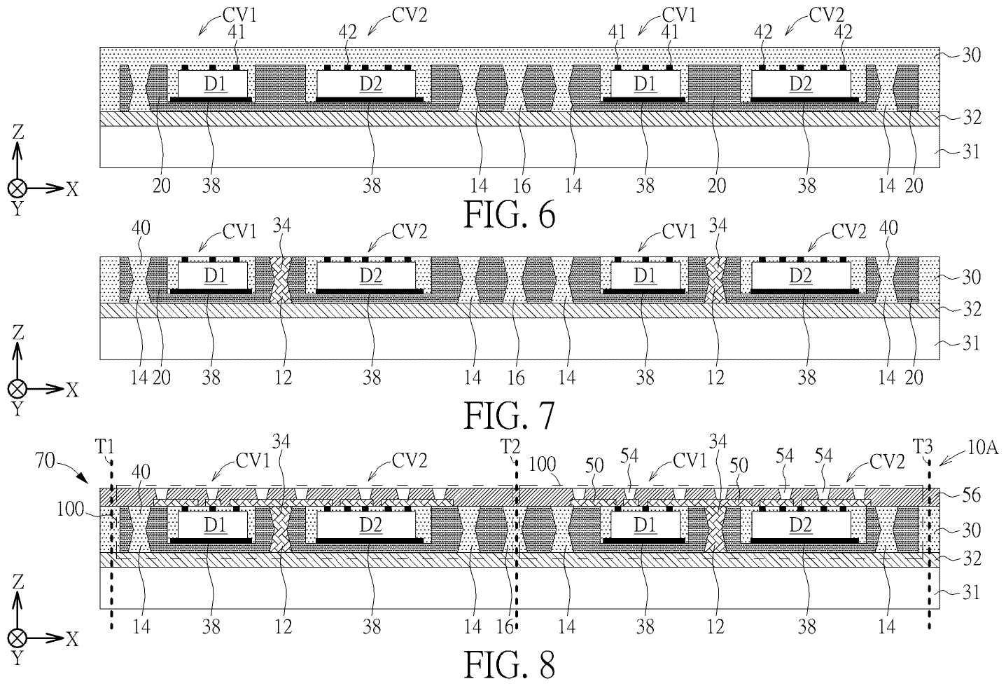

Please refer to FIG. 6 to FIG. 8. FIG. 6 to FIG. 8 are schematic structural diagrams illustrating the manufacturing method of the package structure 10A according to another embodiment of the present disclosure at different steps, wherein FIG. 8 can be regarded as a schematic cross-sectional view corresponding to the package structure 10A of FIG. 1 along the dashed line 5-5′. Different from the manufacturing method of FIG. 3 to FIG. 5, during the execution of the manufacturing method of FIG. 6 to FIG. 8, the contact pads 41 and 42 of the electronic unit D1 and the electronic unit D2 are disposed facing the same direction as the Z-axis, i.e., the active surfaces of the electronic unit D1 and the electronic unit D2 are disposed face-up and facing away from the bottom surfaces of the cavity CV1 and the cavity CV2. First, the substrate 20 can be fixed onto the carrier board 31 by the adhesive layer 32. After the substrate 20 is fixed on the carrier board 31, the through hole 12, cavity CV1, cavity CV2, groove 14, and groove 16 of the substrate 20 can be formed by means of mechanical processing, laser processing, chemical etching, or composite processing. After the cavity CV1 and cavity CV2 of the substrate 20 are formed, as shown in FIG. 6, the electronic unit D1 and the electronic unit D2 are disposed in the cavity CV1 and the cavity CV2, respectively, with their contact pads 41 and 42 facing parallel to the Z-axis direction, and covered with a protection layer 30 over the electronic unit D1, electronic unit D2, and substrate 20. Among them, in the embodiment shown in FIG. 6, the cavity CV1 and the cavity CV2 can be blind holes, respectively having cavity bottom surfaces located within the substrate 20. The electronic unit D1 and the electronic unit D2 can be adhered to the bottom surfaces of the cavity CV1 and the cavity CV2, respectively, by an adhesive layer 38, and the adhesive layer 38 may include, for example, underfill material or other suitable materials. Next, as shown in FIG. 7, a portion of the protection layer 30 is removed, for example, by planarizing the protection layer 30, so that the contact pads 41 and 42 of the electronic unit D1 and the electronic unit D2 are exposed. On the other hand, the through hole 12 can be formed in the substrate 20, and conductive material is filled into the through hole 12 to form the conductive structure 34. Finally, as shown in FIG. 8, a circuit structure 70 is formed on the electronic unit D1 and the electronic unit D2, which may comprise an insulating layer 56 and a plurality of conductive structures 50 and a plurality of conductive structures 54 coupled to the electronic unit D1 and the electronic unit D2, thus completing the fabrication of the package structure 10A. A part of the conductive structure 50 and the plurality of conductive structures 54 may also be coupled to the conductive structure 34, but is not limited thereto. Afterwards, as described above, the package structure 10A can be cut along the cutting lines T1 to T7 to produce six identical components 100.

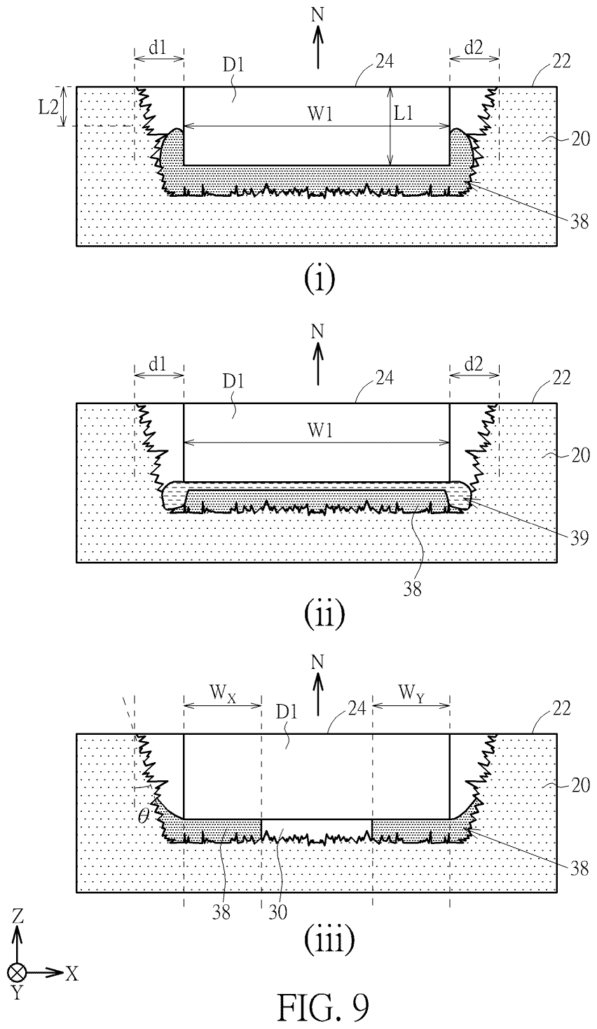

Please refer to FIG. 9. FIG. 9 illustrates several ways (i) to (iii) of disposing the electronic unit D1 of the package structure 10A in FIG. 1 into the cavity CV1. In method (i), the electronic unit D1 is disposed in the cavity CV1 by the adhesive layer 38, and the adhesive layer 38 can completely adhere to the bottom of the electronic unit D1 and partially adhere to the sidewall of the electronic unit D1, such that the shortest distance L2 between the adhesive layer 38 and the first surface 22 of the substrate 20 is smaller than the distance L1 between the bottom of the electronic unit D1 and the first surface 22 of the substrate 20. Furthermore, in the plane parallel to the first surface 22 of the substrate 20, intervals d1 and d2 of 5 to 10 micrometers are left between the top side edges of the electronic unit D1 and the cavity CV1. In method (ii), an additional adhesive layer 39 is added to fill the unevenness of the bottom surface of the cavity CV1, further enhancing the bonding strength between the electronic unit D1 and the substrate 20. In method (iii), the adhesive layer 38 only adheres to the outer portion of the bottom of the electronic unit D1. The adhesive layer 38 adheres to both sides of the bottom of the electronic unit D1, with widths WX and WY in the X-axis direction both smaller than the width W1 of the electronic unit D1, while the inner side of the bottom of the electronic unit D1 is filled by the protection layer 30. This design can effectively reduce stress concentration and improve the durability of the product. Different adhesion methods have different impacts on the performance, reliability, and cost of the product, and engineers can choose the optimal solution based on actual needs. Furthermore, along the normal direction N of the substrate 20, the distance between the top surface 24 of the electronic unit D1 and the first surface 22 of the substrate 20 is less than 10 micrometers. Such a design ensures precise alignment between the electronic unit D1 and the substrate 20, thereby enhancing the overall performance and reliability of the device. As for the method of disposing the electronic unit D2 of the package structure 10A in the cavity CV2, it can also be carried out by analogy with the above methods (i) to (iii), for example: and the distance between the top surface of the electronic unit D2 and the first surface 22 of the substrate 20 can also be less than 10 micrometers.

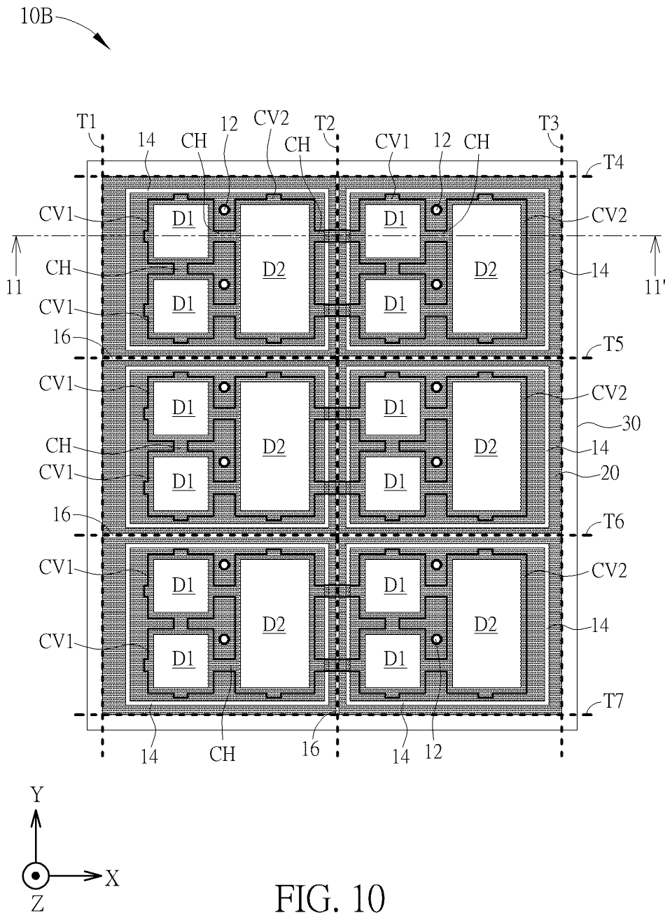

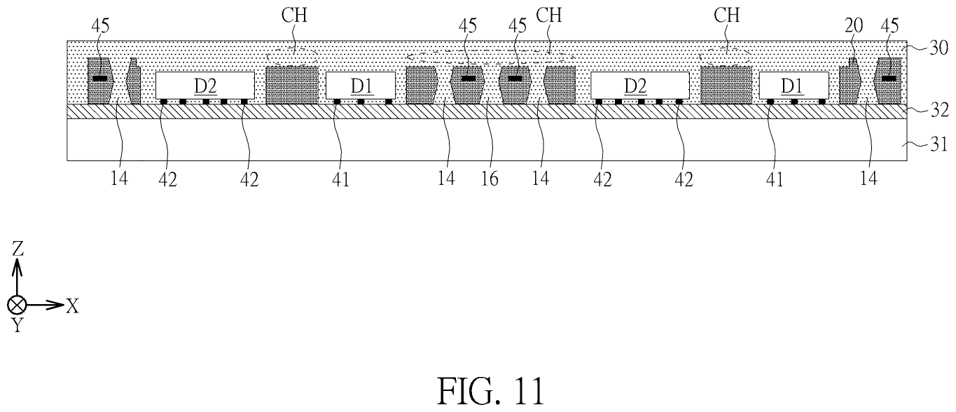

Please refer to FIG. 10 and FIG. 11. FIG. 10 is a top view of a package structure 10B according to another embodiment of the present disclosure, and FIG. 11 is a cross-sectional view of the package structure 10B in FIG. 10 along the dashed line 11-11′. The structure of the package structure 10B is similar to that of the package structure 10A, and the main difference between the two is that: there is a channel CH between the cavity CV1 and the cavity CV2 of the package structure 10B. The bottom R angle of the channel CH can be between 40 micrometers and 50 micrometers. At the channel CH, the thickness of the substrate 20 is smaller, while the portion of the substrate 20 without the channel CH has a greater thickness. The function of the channel CH is mainly to effectively guide the flow of the encapsulation material, thereby reducing bubble generation. The channel CH can be formed simultaneously with the cavity CV1 and the cavity CV2, but is not limited thereto. Furthermore, an alignment mark 45 can be formed in the substrate 20 of the package structure 10B. The alignment mark 45 can be located between the top surface and the bottom surface of the substrate 20, or not exposed on the surface of the substrate 20. Additionally, the alignment mark 45 can be fabricated simultaneously with part of the process for the through hole 12, or simultaneously with part of the process for the cavity CV1 and cavity CV2. The method for fabricating the alignment mark 45, for example, is accomplished through a modification process, and the modification process may include a laser irradiation process or other suitable processes. The alignment mark 45 serves as a precise alignment reference for subsequent processes to improve the yield rate.

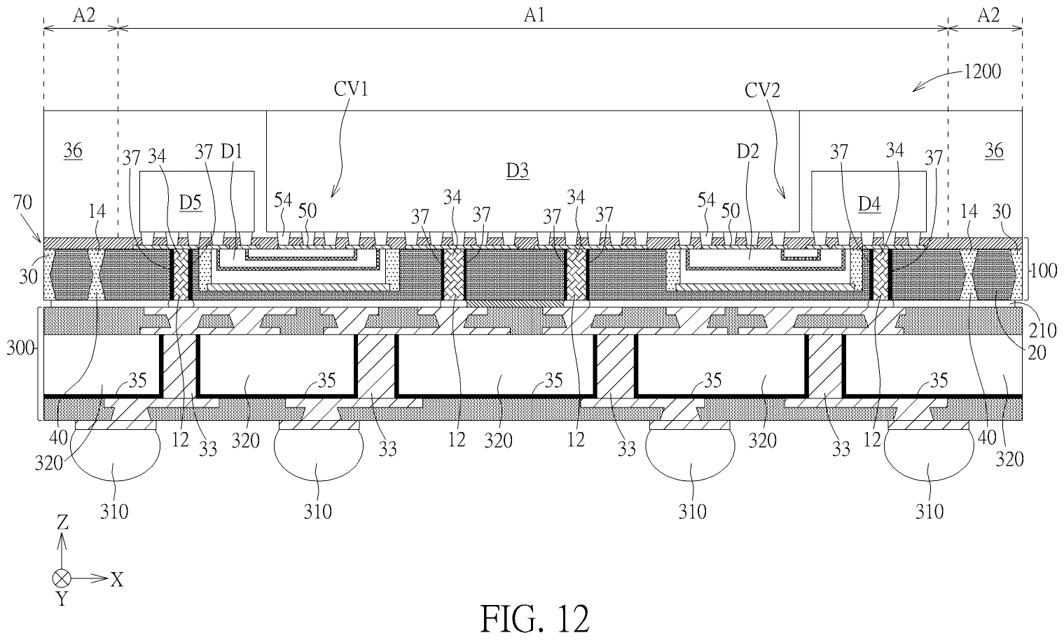

After the component 100 with the outline in the above embodiments is fabricated, the component 100 can be integrated with other electronic units to become the electronic device of the present disclosure. Please refer to FIG. 12. FIG. 12 is a schematic cross-sectional view of an electronic device 1200 according to an embodiment of the present disclosure. In addition to the aforementioned component 100, the electronic device 1200 further comprises an electronic unit D3 disposed on the circuit structure 70 of the component 100. The electronic unit D3 can be coupled to the electronic unit D1 and the electronic unit D2 via the circuit structure 70, and transmit signals mutually with the electronic unit D1 and the electronic unit D2. In other embodiments, the electronic device 1200 may further comprise electronic units D4 and D5 disposed on the circuit structure 70. The electronic units D4 and D5 can be coupled to other electronic units (e.g., electronic units D1, D2, and D3) via the circuit structure 70, and transmit signals mutually with the other electronic units. The electronic units D3, D4, and D5 can be the same or different from each other, and may comprise, for example, integrated circuit chips, redistribution layer (RDL) units, display units, light-emitting units, sensing units, antenna units, touch units, package units, or other suitable electronic units, but are not limited thereto. The electronic device 1200 may further comprise a redistribution structure (RDL) 300, which is connected to the bottom of the component 100 via a dielectric layer 210. The redistribution structure 300 may comprise at least one conductive layer and at least one insulating layer, or redistribute lines and/or further enhance the line fan-out area, or allow different electronic components (e.g., electronic units D1 to D5) to be electrically connected to each other through the redistribution structure 300, or serve as a substrate for electrical interface wiring between one connection and another. The formation method of the redistribution structure 300 comprises, for example: providing a stack of at least one insulating layer and at least one conductive layer, and its process comprises processes such as pressing, heating, photolithography, etching, surface treatment, laser, plating, etc. Surface treatment includes roughening the surface of the insulating layer or the conductive layer to enhance its adhesion ability. The purpose of the redistribution structure 300 is to expand the connections to a wider pitch or redistribute the connections to another connection with a different pitch. The dielectric layer of the redistribution structure 300 can be polyimide (PI), polyphenylene sulfide (PSPI), polybenzoxazole (PBO), epoxy, polymer, aniline-benzimidazole copolymer (ABF), silicon oxide (SiOx), or silicon nitride (SiNx). The electronic device 1200 may further comprise connecting elements 310 disposed at the bottom of the redistribution structure 300 and coupled to the conductive structure 33 of the redistribution structure 300. The connecting element 310 may comprise, for example, solder balls, nickel, gold, copper, gallium, or other suitable conductive materials, and can serve as electronic terminals for transmitting signals between the electronic device 1200 and the exterior. The conductive structure 33 may comprise copper, aluminum, gold, silver, or other suitable conductive materials, and serves as the main structure for transmitting electrical signals in the redistribution structure 300. The redistribution structure 300 may further comprise a buffer layer 35 to buffer the stress between the conductive structure 33 and other structures. That is, the buffer layer 35 can be disposed between the conductive structure 33 and the substrate 320 to buffer stress, wherein the material of the substrate 320 can be similar to the substrate 20. According to some embodiments, the stiffness of the substrate 320 can be greater than that of the substrate 20, and along the normal direction of the electronic device 1200, the thickness of the substrate 320 can be greater than that of the substrate 20 to enhance the supportability of the electronic device 1200, but is not limited thereto. The buffer layer 35 can absorb and disperse these stresses to reduce damage to the redistribution structure 300, thereby improving the reliability of the product. In some embodiments of the present disclosure, a buffer layer 37 can be formed on the sidewall of the through hole 12 to buffer the stress between the conductive structure 34 and other structures. The toughness of the buffer layer 35 and the buffer layer 37 can be greater than the toughness of the protection layer 30 and the substrate 20, for example, between 0.1 and 100 kJ/m², and the material of the buffer layer 35 and the buffer layer 37 can be polyimide, parylene, BCB (bisbenzocyclobutene), epoxy resin (e.g., Epoxy Molding Compounds, EMC), polycarbonate, polyethylene terephthalate, polyethylene naphthalate, etc., but is not limited to the above. Furthermore, an encapsulation layer 36 can be formed on the electronic units D4 and D5, and the encapsulation layer 36 comprises filler particles. Therefore, the toughness of the encapsulation layer 36 can be smaller than the toughness of the protection layer 30, and the material of the encapsulation layer 36 can be polyimide, parylene, BCB (bisbenzocyclobutene), epoxy resin (e.g., EMC), polycarbonate, polyethylene terephthalate, polyethylene naphthalate, etc. The filler particles may include oxides, nitrides, carbides, combinations thereof, or other suitable materials, but are not limited thereto. In this embodiment, the component 100 of the electronic device 1200 comprises a crack stopper 40 located in the peripheral area A2 of the substrate 20, while the electronic units D1 and D2 are located in the central area A1 of the substrate 20. Furthermore, in the component 100, the outer sidewall of the substrate 20 has the protection layer 30. The toughness referred to in this case is measured, for example, using the standard test method for polymer matrix composite materials (ASTM D3039/D3039M). Specifically, first separate the member to be subjected to the tensile test from the component 100; then, pre-mark two gauge marks on said member, wherein the distance between the two gauge marks is called the gage length; then, perform tension on said member using a tensile testing machine (e.g., universal testing machine), so that the gage length gradually elongates during the tensile test process. The toughness can be obtained by calculating the area under the stress-strain curve (e.g., by integration).

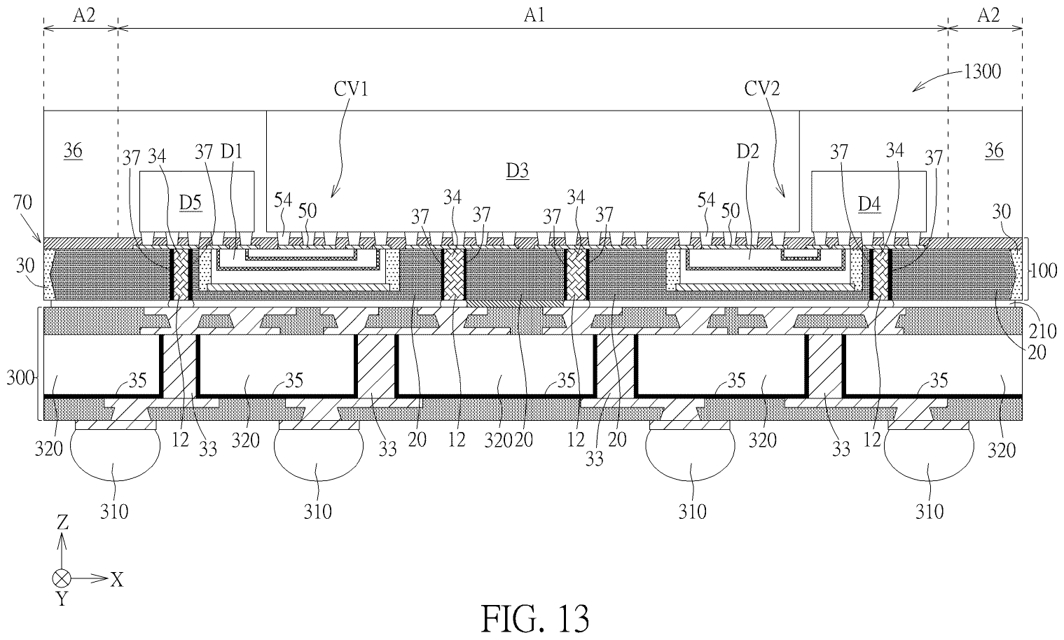

Please refer to FIG. 13. FIG. 13 is a schematic cross-sectional view of an electronic device 1300 according to an embodiment of the present disclosure. The structure of the electronic device 1300 is similar to that of the electronic device 1200, and the main difference between the two is that: the electronic device 1300 does not have the crack stopper 40 present in the electronic device 1200.

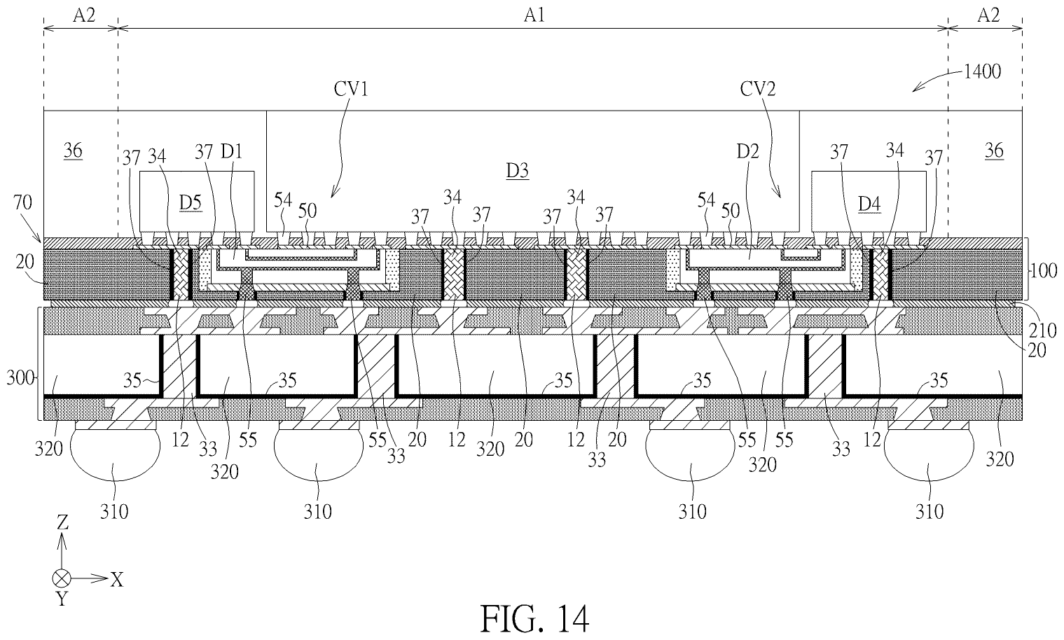

Please refer to FIG. 14. FIG. 14 is a schematic cross-sectional view of an electronic device 1400 according to an embodiment of the present disclosure. The structure of the electronic device 1400 is similar to that of the electronic device 1300, and the main difference between the two is that: the component 100 of the electronic device 1400 further comprises a conductive structure 55 disposed on the bottom surface of the component 100 and coupled to the electronic units D1 and D2 and the redistribution structure 300. That is, the electronic unit D1 and/or the electronic unit D2 can be respectively coupled to the redistribution structure 300 via the conductive structure 55.

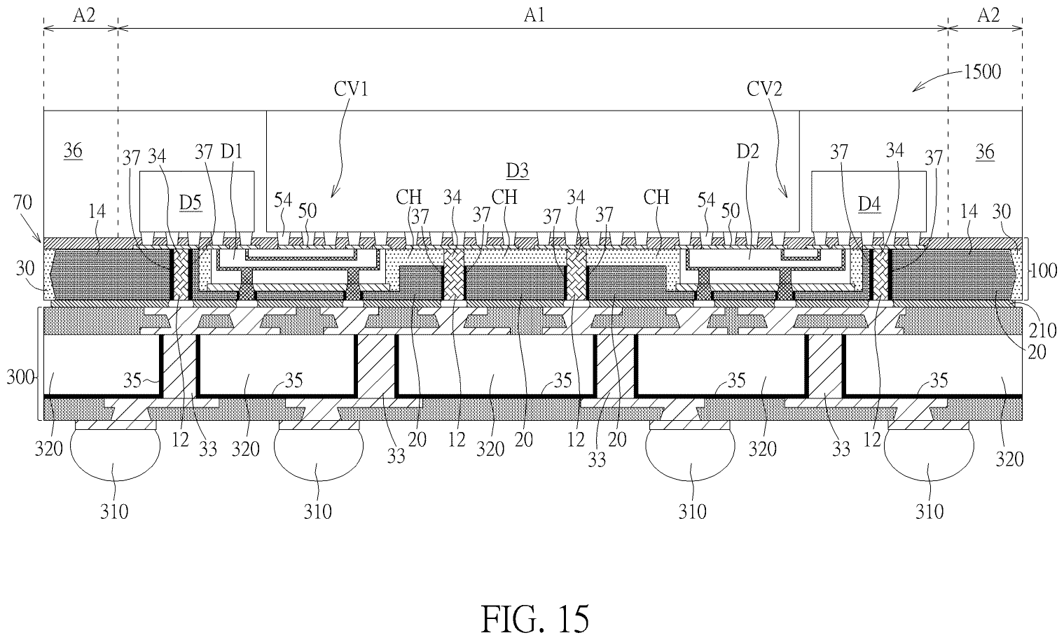

Please refer to FIG. 15. FIG. 15 is a schematic cross-sectional view of an electronic device 1500 according to an embodiment of the present disclosure. The structure of the electronic device 1500 is similar to that of the electronic device 1300, and the main difference between the two is that: there is the channel CH mentioned in the above embodiments between the cavity CV1 and the cavity CV2 in the electronic device 1500. At the channel CH, the thickness of the substrate 20 is smaller. In other words, the thickness of the substrate 20 in the peripheral area A2 can be greater than the thickness of the substrate 20 in the central area A1.

In the electronic device of the above embodiments, the substrate has a through hole, a first cavity, and a second cavity. The first electronic unit is disposed in the first cavity, and the second electronic unit is disposed in the second cavity. Due to the constraints of the first cavity and the second cavity, during the packaging process of manufacturing the component of the electronic device, the shift amount of the first electronic unit and the second electronic unit can be effectively controlled, thereby improving the yield rate and reliability of the product.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate having a first surface, a second surface opposite the first surface, a first cavity, and a second cavity, wherein a sidewall of the first cavity is connected to the first surface, and a sidewall of the second cavity is connected to the first surface;
a through hole extending through the substrate, wherein a sidewall of the through hole is connected to the first surface and the second surface;
a first electronic unit disposed in the first cavity;
a second electronic unit disposed in the second cavity;
a circuit structure disposed on the first electronic unit and the second electronic unit; and
a third electronic unit disposed on the circuit structure;
wherein a roughness of a bottom surface of the first cavity and a roughness of a bottom surface of the second cavity range from 0 to 2 micrometers.

2. The electronic device of claim 1, wherein a difference between the roughness of the bottom surface of the first cavity and the roughness of the bottom surface of the second cavity is less than 1.2 micrometers.

3. The electronic device of claim 1, wherein the first cavity has a first bottom corner and a second bottom corner, the second cavity has a third bottom corner and a fourth bottom corner, and a difference between the first bottom corner and the second bottom corner and a difference between the third bottom corner and the fourth bottom corner are both greater than or equal to 0 degrees and less than or equal to 10 degrees.

4. The electronic device of claim 1, wherein a width of the first cavity is greater than a width of the first electronic unit, and a width of the second cavity is greater than a width of the second electronic unit.

5. The electronic device of claim 1, further comprising a protection layer disposed on a sidewall of the substrate, wherein a toughness of the protection layer is greater than a toughness of the substrate.

6. The electronic device of claim 1, further comprising a crack stopper located in a peripheral area of the substrate, wherein a toughness of the crack stopper is greater than a toughness of the substrate.

7. The electronic device of claim 6, wherein the substrate is fixed onto a carrier board by an adhesive layer.

8. The electronic device of claim 1, wherein a channel is provided between the first cavity and the second cavity.

9. The electronic device of claim 1, further comprising a conductive structure disposed in the through hole.

10. The electronic device of claim 1, wherein, along a normal direction of the substrate, a distance between a top surface of the first electronic unit and the first surface of the substrate is less than 10 micrometers, and a distance between a top surface of the second electronic unit and the first surface of the substrate is less than 10 micrometers.

11. A manufacturing method of an electronic device, comprising:
providing a substrate having a first surface and a second surface opposite the first surface;
forming a through hole in the substrate, wherein a sidewall of the through hole is connected to the first surface and the second surface;
forming a first cavity and a second cavity in the substrate, wherein a sidewall of the first cavity is connected to the first surface, a sidewall of the second cavity is connected to the first surface, and a roughness of a bottom surface of the first cavity and a roughness of a bottom surface of the second cavity range from 0 to 2 micrometers;
disposing a first electronic unit in the first cavity;
disposing a second electronic unit in the second cavity;
forming a protection layer on the substrate, covering the first electronic unit and the second electronic unit and filling the first cavity, and the second cavity;
forming a circuit structure on the first electronic unit and the second electronic unit; and
disposing a third electronic unit on the circuit structure.

12. The manufacturing method of the electronic device of claim 11, wherein a difference between the roughness of the bottom surface of the first cavity and the roughness of the bottom surface of the second cavity is less than 1.2 micrometers.

13. The manufacturing method of the electronic device of claim 11, wherein the first cavity has a first bottom corner and a second bottom corner, the second cavity has a third bottom corner and a fourth bottom corner, and a difference between the first bottom corner and the second bottom corner and a difference between the third bottom corner and the fourth bottom corner are both greater than or equal to 0 degrees and less than or equal to 10 degrees.

14. The manufacturing method of the electronic device of claim 11, further comprising:
forming an alignment mark in the substrate.

15. The manufacturing method of the electronic device of claim 11, wherein when forming the protection layer, the protection layer further fills the through hole, and the manufacturing method further comprises:
performing a cutting process along the through hole, such that a sidewall of the substrate after cutting is covered by the protection layer, wherein a toughness of the protection layer is greater than a toughness of the substrate.

16. The manufacturing method of the electronic device of claim 11, further comprising:
forming a crack stopper in a peripheral area of the substrate, wherein a toughness of the crack stopper is greater than a toughness of the substrate.

17. The manufacturing method of the electronic device of claim 16, further comprising:
fixing the substrate onto a carrier board using an adhesive layer.

18. The manufacturing method of the electronic device of claim 11, further comprising:
forming a channel between the first cavity and the second cavity, wherein when forming the protection layer, the protection layer fills the channel.

19. The manufacturing method of the electronic device of claim 11, further comprising:
forming a conductive structure in the through hole.

20. The manufacturing method of the electronic device of claim 11, wherein, along a normal direction of the substrate, a distance between a top surface of the first electronic unit and the first surface of the substrate is less than 10 micrometers, and a distance between a top surface of the second electronic unit and the first surface of the substrate is less than 10 micrometers.
